(19) United States
(12) Patent Application Publication
(10) Pub. No.: US 2020/0131627 A1
(43) Pub. Date: Apr. 30, 2020

(54) HEAT TREATMENT APPARATUS FOR A VACUUM CHAMBER, DEPOSITION APPARATUS FOR DEPOSITING MATERIAL ON A FLEXIBLE SUBSTRATE, METHOD OF HEAT TREATMENT OF A FLEXIBLE SUBSTRATE IN A VACUUM CHAMBER, AND METHOD FOR PROCESSING A FLEXIBLE SUBSTRATE

(71) Applicants: Fabio PIERALISI, Aschaffenburg (DE); Gerhard STEINIGER, Ronneburg (DE); Horst ALT, Neuberg (DE); Applied Materials, Inc., Santa Clara, CA (US)

(72) Inventors: Fabio PIERALISI, Aschaffenburg (DE); Gerhard STEINIGER, Ronneburg (DE); Horst ALT, Neuberg (DE)

(21) Appl. No.: 16/627,057

(22) PCT Filed: Jul. 21, 2017
(86) PCT No.: PCT/EP2017/068507

§ 371 Date: Dec. 27, 2019

(51) Int. Cl. C23C 16/02; C23C 16/54; F28F 5/02

(52) U.S. Cl. CPC C23C 16/0209; F28F 5/02; C23C 16/545

(57) ABSTRACT

The present disclosure provides a heat treatment apparatus (100) for use in a vacuum chamber (101). The heat treatment apparatus (100) includes a transport arrangement configured to apply a tension to a flexible substrate (10) in a longitudinal direction, wherein the transport arrangement comprises a drum (110), and a heating device configured to heat the drum (110) for heating the flexible substrate (10) to a first temperature of 120° C. to 180° C.

### FIELD

Embodiments of the present disclosure relate to a heat treatment apparatus for use in a vacuum chamber, a deposition apparatus for depositing material on a flexible substrate, a method of heat treatment of a flexible substrate in a vacuum chamber, and a method for processing a flexible substrate. Embodiments of the present disclosure particularly relate to thin-film processing apparatuses, for example, to an apparatus for processing a flexible substrate, and more particularly to roll-to-roll (R2R) systems.

### BACKGROUND

Processing of flexible substrates, such as plastic films or foils, can be employed in the packaging industry, semiconductor industry and other industries. The processing may include a coating of the flexible substrate with one or more coating materials, such as metals, semiconductor materials and dielectric materials. Processing apparatuses performing the processing aspects can include a coating drum coupled to a system for transportation of the flexible substrate. Such roll-to-roll systems can provide a high throughput.

A manufacturing process of a flexible substrate can give rise to non-uniformity in mechanical properties, such as internal stress and winding hardness differences in a transverse direction (TD). Moreover, there can be a significant change in the mechanical properties of the flexible substrate at higher temperatures. For example, the Elastic Modulus of PET films can sharply decrease above a certain temperature, and the resulting decrease in film stiffness negatively affects the film handling. These factors have a strong impact on the winding performance (e.g. waves, wrinkle formation) at higher process heat loads, like heat loads inherent in Chemical Vapor Deposition (CVD).

In view of the above, new heat treatment apparatuses for use in a vacuum chamber, deposition apparatuses for depositing material on a flexible substrate, methods of heat treatment of a flexible substrate in a vacuum chamber, and methods for processing a flexible substrate that overcome at least some of the problems in the art, are beneficial. Specifically, apparatuses and methods are beneficial that can stabilize the flexible substrate.

### SUMMARY

In light of the above, a heat treatment apparatus for use in a vacuum chamber, a deposition apparatus for depositing material on a flexible substrate, a method of heat treatment of a flexible substrate in a vacuum chamber, and a method for processing a flexible substrate are provided. Further aspects, benefits, and features of the present disclosure are apparent from the claims, the description, and the accompanying drawings.

According to an aspect of the present disclosure, a heat treatment apparatus for use in a vacuum chamber is provided. The apparatus includes a transport arrangement configured to apply a tension to a flexible substrate in a longitudinal direction, wherein the transport arrangement comprises a drum, and a heating device configured to heat the drum for heating the flexible substrate to a first temperature of 120° C. to 180° C.

According to a further aspect of the present disclosure, a heat treatment apparatus for use in a vacuum chamber is provided. The apparatus includes a transport arrangement configured to apply a tension to a flexible substrate in a longitudinal direction, and a heating device having a drum which is configured to heat the flexible substrate to a first temperature of 120° C. to 180° C.

According to another aspect of the present disclosure, a deposition apparatus for depositing material on a flexible substrate is provided. The apparatus includes a vacuum chamber, a heat treatment apparatus according to the present disclosure in the vacuum chamber, and one or more deposition devices for depositing material on at least a surface of the flexible substrate, specifically wherein the heating device is positioned before the one or more deposition devices.

According to a further aspect of the present disclosure, a method of heat treatment of a flexible substrate in a vacuum chamber is provided. The method includes transporting the flexible substrate, applying a tension to the flexible substrate in a longitudinal direction, and heating, using a drum, the flexible substrate to a first temperature of 120° C. to 180° C.

According to a yet further aspect of the present disclosure, a method for processing a flexible substrate is provided. The method includes transporting the flexible substrate, applying a tension to the flexible substrate in a longitudinal direction, heating, using a drum, the flexible substrate to a first temperature of 120 to 180° C., and depositing material on at least a surface of the flexible substrate.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic cross-sectional view of a heat treatment apparatus for use in a vacuum chamber according to embodiments described herein;

FIG. 2 shows a schematic cross-sectional view of a heat treatment apparatus for use in a vacuum chamber according to further embodiments described herein;

FIG. 3 shows a flow chart of a method of heat treatment of a flexible substrate in a vacuum chamber according to embodiments described herein;

FIGS. 4A and B illustrate a shrinkage of a flexible substrate;

FIG. 5 shows a schematic cross-sectional view of a deposition apparatus for depositing material on a flexible substrate according to embodiments described herein; and

FIG. 6 shows a flow chart of a method for processing a flexible substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

A manufacturing process of a flexible substrate, such as a PET film, can give rise to non-uniformity in mechanical properties, such as internal stress and winding hardness differences in a machine direction (MD) and/or a transverse direction (TD). Moreover, there can be a significant change in the mechanical properties of the flexible substrate at higher temperatures. For example, the Elastic Modulus of PET films can sharply decrease above a certain temperature, and the resulting decrease in film stiffness negatively affects the film handling. These factors have a strong impact on the winding performance (e.g. waves, wrinkle formation) at higher process heat loads, like heat loads inherent to Chemical Vapor Deposition (CVD).

The present disclosure provides a heat stabilization through heated winding under vacuum, allowing a flexible substrate, such as a PET film or foils, to relax particularly in the transverse direction. The stabilization process reduces mechanical non-uniformities in the flexible substrate. Winding hardness non-uniformities in the transverse direction can be removed and a formation of waves and wrinkles can be reduced or even avoided.

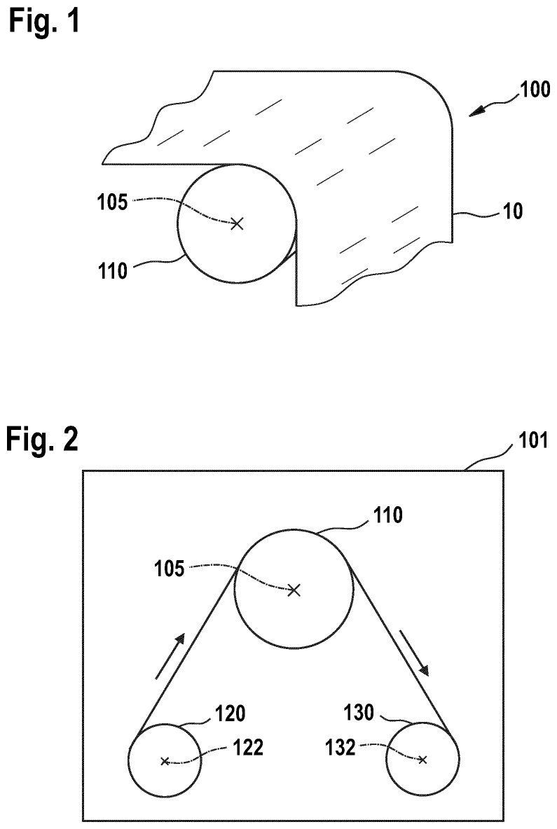

FIG. 1 shows a schematic cross-sectional view of a heat treatment apparatus 100 for a vacuum chamber 101 according to embodiments described herein.

The apparatus 100 includes a transport arrangement configured to apply a tension to a flexible substrate 10 in a longitudinal direction, wherein the transport arrangement comprises a drum 110, and a heating device configured to heat the drum 110 for heating the flexible substrate 10 to a first temperature of 120 to 180° C. The apparatus 100 can be provided in a vacuum chamber 101. In some implementations, the apparatus 100 can include the vacuum chamber 101. Specifically, the drum 110 can be provided inside the vacuum chamber 101 such that the heat treatment can be performed in a vacuum.

The drum 110 is a heatable or heated drum. The heating device is configured to heat the drum 110, and can be particularly configured to heat a support surface of the drum 110. The heating device can be integrated in the drum 100 or can be provided separately. For example, the heating device can be selected from the group including a radiation heater, a resistive heater, and a combination thereof. The drum can heat the flexible substrate by contacting the flexible substrate 10.

The heat stabilization through heated winding under tension and vacuum allows the flexible substrate 10 to relax e.g. in the transverse direction (TD). The transverse direction can be essentially perpendicular to the longitudinal direction and/or the machining direction (MD). The longitudinal direction of the flexible substrate 10 can be defined along, or parallel to, the transport direction provided by the transport arrangement and/or along, or parallel to, the machine direction (MD). The longitudinal direction can be along a length extension of the flexible substrate. The transverse direction (TD), the machining direction (MD), and the longitudinal direction can be defined in a plane of a surface, such as an upper surface or a lower surface, of the flexible substrate 10. The transport arrangement can be configured to apply the tension to the flexible substrate 10.

The term “vacuum” as used throughout the present disclosure can be understood in the sense of a technical vacuum having a vacuum pressure of less than, for example, 10 mbar. One or more vacuum pumps, such as turbo pumps and/or cryo-pumps, can be connected to the vacuum chamber for generation of the vacuum. The term “tension” as used throughout the present disclosure can be understood in the sense of a “pulling force” exerted on the flexible substrate. Specifically, “tension” is the opposite of “compression”. The term “flexible substrate” as used herein shall embrace flexible substrates such as a film, web or foil. It is noted here that a flexible substrate as used within the embodiments described herein can be characterized in that it is bendable.

The drum 110 can be rotatable around a rotational axis 105. The drum 110 has a support surface configured for supporting the flexible substrate 10. Specifically, the drum 110 is configured to support the flexible substrate 10 during the heat treatment in the vacuum chamber 101. The term “support surface” refers to a surface configured to contact the flexible substrate 10 for supporting the flexible substrate 10. The apparatus 100 can be configured such that a length of a contact portion (or contact area or contact path) of the flexible substrate 10 in the longitudinal direction that contacts the support surface is at least 1 m, specifically at least 2 m, and more specifically at least 2.5 m. For example, the length of the contact portion can be in a range between 1 m and 3 m, specifically in a range between 1.5 m and 2.5 m, and can more specifically be about 2 m.

The support surface can be provided by a circumferential surface, such as an outer circumferential surface, of the drum 110. In some implementations, the drum 110 can be substantially cylindrical, wherein the support surface can be provided by the circumferential surface of the substantially cylindrical drum. The support surface can be symmetrical with respect to the rotational axis 105. For example, the support surface can be substantially rotationally symmetric around the rotational axis 105. The drum 110 can also be referred to as “substrate support”.

The transport arrangement can be configured to rotate the drum 110 around the rotational axis 105 such that the flexible substrate 10 is moved forward or backward. For example, the drum 110 is rotatable in a first direction and a second direction opposite the first direction. The drum 110 can be configured to heat the flexible substrate 10 to the first temperature during the rotation of the drum 110 in the first direction. The first direction can be a clockwise direction and the second direction can be a counterclockwise direction, or the first direction can be a counterclockwise direction and the second direction can be a clockwise direction. According to some embodiments, which can be combined with other embodiments described herein, the drum 110 is configured to heat the flexible substrate 10 to a second temperature lower than the first temperature during the rotation of the drum 110 in the second direction. For example, the second temperature can be in the range between 50 and 90° C.

The drum 110, and particularly the support surface, can have a width in a direction parallel to the rotational axis 105. The width can be defined between the peripheries of the drum 110, and particularly the peripheries of the support surface. The width can be at least 300 mm, specifically at least 1 m, and more specifically at least 3 m. For example, the width can be in a range between 300 mm and 5 m, and can more specifically be in a range between 400 mm and 4.5 m. According to some embodiments, which can be combined with other embodiments described herein, a diameter of the drum 110 is at least 300 mm, specifically at least 0.5 m, and more specifically at least 1 m. In particular, the diameter of the drum 110 can be at least 0.5 m. The diameter can be in a range between 300 mm and 3 m, specifically in a range between 400 mm and 2 m, and more specifically in a range between 400 mm and 1.8 m.

FIG. 2 shows a schematic cross-sectional view of a heat treatment apparatus for a vacuum chamber according to further embodiments described herein.

According to some embodiments, which can be combined with other embodiments described herein, the transport arrangement includes a first roller 120 and a second roller 130. The first roller 120, the drum 110, and the second roller 130 can be sequentially arranged along a transport path of the flexible substrate 10. The first roller 120 can be rotatable around a first rotational axis 122. Likewise, the second roller 130 can be rotatable around a second rotational axis 132. The rotational axis 105 of the drum 110, the first rotational axis 122 of the first roller 120, and the second rotational axis 132 of the second roller 130 can be substantially parallel. The term “substantially parallel” relates to a substantially parallel orientation of the rotational axes, wherein a deviation of a few degrees, e.g. up to 50 or even up to 100, from an exact parallel orientation is still considered as “substantially parallel”. The rotational axis 105 of the drum 110, the first rotational axis 122 of the first roller 120, and the second rotational axis 132 of the second roller 130 can be substantially horizontal rotational axes.

The first roller 120 can be rotatable in the first direction and optionally the second direction, and the second roller 130 can be rotatable in the first direction and optionally the second direction. The drum 110, the first roller 120, and the second roller 130 can rotate essentially synchronously in the same direction, such as the first direction or the second direction. The transport arrangement can be configured to control the rotation of at least one of the drum 110, the first roller 120, and the second roller 130 such that the tension is applied to the flexible substrate 10. In particular, the transport arrangement can be configured to provide the tension to the flexible substrate 10 during the transportation and/or the heat treatment of the flexible substrate 10.

In some implementations, the first roller 120 and the second roller 130 can be selected from the group including a winding roller, an unwinding roller, and a combination thereof. For example, the first roller 120 is an unwinding roller and the second roller 130 is a winding roller when the drum 110 rotates in the first direction. Likewise, the first roller 120 can be a winding roller and the second roller 130 can be an unwinding roller when the drum 110 rotates in the second direction.

According to some embodiments, which can be combined with other embodiments described herein, the apparatus can be configured to sequentially rotate the drum 110 (and optionally the first roller 120 and/or the second roller 130) in the first direction and the second direction. For example, the apparatus can be configured to rotate the drum 110 in the first direction for transportation of the flexible substrate 10 in a forward direction and afterwards in the second direction for transportation of the flexible substrate 10 in a backward direction. During the transportation of the flexible substrate 10 in the forward direction, as is illustrated in FIG. 2, the first roller 120 can act as an unwinding roller and the second roller 130 can act as a winding roller. During the transportation of the flexible substrate 10 in the backward direction, the first roller 120 can act as a winding roller and the second roller 130 can act as an unwinding roller.

According to some embodiments, which can be combined with other embodiments described herein, the apparatus, and particularly the drum 110, is configured to heat the flexible substrate 10 to a second temperature lower than the first temperature. For example, the apparatus is configured to first heat the flexible substrate 10 to the first temperature and afterwards to the second temperature. The first temperature is in a range between 120° C. and 180° C., specifically in a range between 130° C. and 170° C., and more specifically in a range between 140° C. and 160° C. For example, the first temperature can be about 150° C. In some implementations, the second temperature is in a range between 40° C. and 100° C., specifically in a range between 50° C. and 90° C., and more specifically in a range between 60° C. and 80° C. For example, the second temperature can be about 70° C.

The apparatus, and particularly the drum 110, can be configured to heat the flexible substrate 10 to the first temperature during the rotation in the first direction and to the second temperature during the rotation in the second direction. The heat treatment at two different temperatures can further improve the dimensional stability of the heat-treated flexible substrate.

The apparatus is configured to apply the tension to the flexible substrate 10 in the longitudinal direction. According to some embodiments, which can be combined with other embodiments described herein, the tension can include a first tension provided to the flexible substrate 10 between the first roller 120 and the drum 110 and a second tension provided to the flexible substrate 10 between the second roller 130 and the drum 110. In some implementations, the first tension and the second tension can be essentially identical. In further implementations, the first tension and the second tension can be different. The flexible substrate 10 mechanically contacts the drum 110 (i.e., there is a frictional force between the support surface and the flexible substrate 10) and thus the first tension and the second tension can be different.

According to some embodiments, the tension between the drum 110 and the roller acting as the unwinding roller can be higher than the tension between the drum 110 and the roller acting as the winding roller. In some implementations, the tension between the drum 110 and the roller acting as the unwinding roller can be at least 1%, specifically at least 5%, specifically at least 10%, and more specifically at least 15% higher than the tension between the drum 110 and the roller acting as the winding roller. In the example of FIG. 2, the first roller 120 acts as the unwinding roller and the second roller 130 acts as the winding roller. The first tension between the first roller 120 and the drum 110 can be higher than the second tension between the drum 110 and the second roller 130. For example, the first tension can be about 750N and the second tension can be about 730N. However, the present disclosure is not limited thereto and the tension between the drum 110 and the roller acting as the winding roller can be higher than the tension between the drum 110 and the roller acting as the unwinding roller. In some implementations, the tension between the drum 110 and the roller acting as the winding roller can be at least 1%, specifically at least 5%, specifically at least 10%, and more specifically at least 15% higher than the tension between the drum 110 and the roller acting as the unwinding roller.

According to some embodiments, which can be combined with other embodiments described herein, the apparatus, and particularly the transport arrangement, is configured to apply a tension, such as the first tension and/or the second tension, in the range between 200N and 900N to the flexible substrate 10, specifically in a range between 400N and 900N, and more specifically in a range between 700N and 800N.

According to some embodiments, which can be combined with other embodiments described herein, the apparatus, and particularly the transport arrangement, is configured to transport the flexible substrate 10 with a speed of 0.1 to 5 m/min, specifically 0.1 to 2 m/min, and specifically 0.2 to 1 m/min. In some implementations, the transport arrangement can be configured to rotate at least one of the drum 110, the first roller 120 and the second roller 130 to transport the flexible substrate with a speed of 0.1 m/min to 5 m/min.

In some embodiments, the transport arrangement can be configured to transport the flexible substrate 10 based on a rotation direction of the drum 110, the first roller 120 and the second roller 130. For example, the transport arrangement can be configured to transport the flexible substrate 10 with a first speed when the drum 110, the first roller 120 and the second roller 130 rotate in the first direction and with a second speed when the drum 110, the first roller 120 and the second roller 130 rotate in the second direction. In other examples, the transport arrangement can be configured to transport the flexible substrate with the first speed when the drum 110, the first roller 120 and the second roller 130 rotate in the second direction and with the second speed when the drum 110, the first roller 120 and the second roller 130 rotate in the first direction. According to some embodiments, the first speed and/or the second speed can be in the range between 0.1 and 5 m/min, specifically in the range between 0.1 and 2 m/min, and more specifically in the range between 0.2 and 1 m/min.

The first speed and the second speed can be essentially identical or can be different. For example, the first speed can be smaller than the second speed. Specifically, the smaller first speed can be used when the flexible substrate 10 is heated to the first temperature and the large second speed can be used when the flexible substrate 10 is heated to the second temperature lower than the first temperature. For example, the first speed can be about 0.2 m/min and the first temperature can be about 150° C. with unwinder/rewinder tensions of 750/730N, respectively. Such tension values can be particularly beneficial for a 125 μm thick, 1270 mm-wide PET roll (different thicknesses/widths can have different tensions). The second speed can be about 1 m/min and the second temperature can be about 70° C. with unwinder/rewinder tensions of 750/730N, respectively.

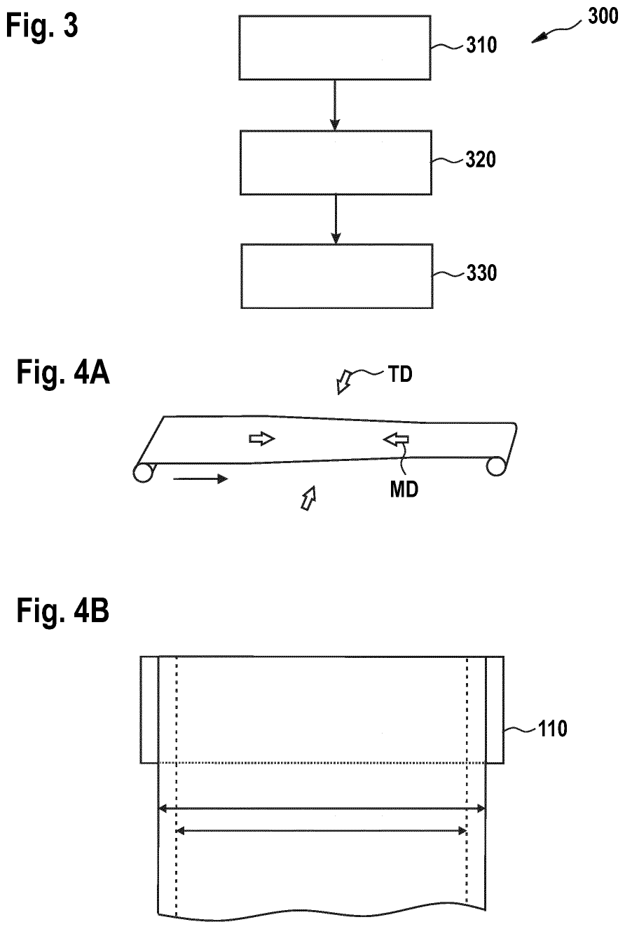

FIG. 3 shows a flow chart of a method 300 of heat treatment of a flexible substrate in a vacuum chamber according to embodiments described herein. The method 300 can utilize, and implement the features of, the apparatus illustrated with respect to FIGS. 1 and 2.

The method 300 includes, in block 310, transporting the flexible substrate, in block 320 applying a tension to the flexible substrate in a longitudinal direction, and in block 330 heating, by a drum, the flexible substrate to a first temperature of 120° C. to 180° C. The flexible substrate can be transported by rotating the drum in a first direction and optionally in a second direction opposite to the first direction.

According to some embodiments, the flexible substrate is heated to the first temperature during the rotation in the first direction and to a second temperature lower than the first temperature during the rotation in the second direction. The first temperature is in the range between 120 and 180° C., specifically in a range between 130 and 170° C., and more specifically in a range between 140 and 160° C. For example, the first temperature can be about 150° C. In some implementations, the second temperature is in a range between 40° C. and 100° C., specifically in a range between 50° C. and 90° C., and more specifically in a range between 60° C. and 80° C. For example, the second temperature can be about 70° C.

In some implementations, a tension of 200N to 900N is applied to the flexible substrate in the longitudinal direction. As explained with respect to FIG. 2, the tension between the drum and the roller acting as the unwinding roller can be higher than the tension between the drum 110 and the roller acting as the winding roller.

According to some embodiments, the flexible substrate is transported with a speed of 0.1 to 5 m/min. For example, the flexible substrate is transported with the first speed during the rotation of the drum in the first direction and with the second speed lower than the first speed during the rotation of the drum in the second direction. The first speed and the second speed can be essentially identical or can be different. For example, the first speed can be smaller than the second speed.

According to embodiments described herein, the method of heat treatment of a flexible substrate in a vacuum chamber can be conducted using computer programs, software, computer software products and the interrelated controllers, which can have a CPU, a memory, a user interface, and input and output devices being in communication with the corresponding components of the apparatuses according to the present disclosure.

FIGS. 4A and B illustrate a shrinkage of a flexible substrate. Due to excellent properties and lower cost, polyester (PET) films can be used as substrates in thin film vacuum deposition processes. For advanced applications, where dimensional stability at higher processing temperatures is beneficial (e.g. flexible electronics, photovoltaic, flat panel displays, and the like), PET films can be heat stabilized when passed through a high temperature offline oven with very low film tensions applied. As is illustrated in FIG. 4A, following the relaxation of the strains induced in PET film processing, shrinkage is reduced in both machine direction (MD) and transverse direction (TD). Once a PET film has shrunk at a particular temperature, there is virtually no further shrinkage as long as that temperature is reached. For an exemplary PET film, when a heat stabilization process temperature is 150° C., the nominal shrinkage at 150° C. is 0.1/0.02% in the MD/TD, respectively.

Yet, the raw PET film manufacturing process gives rise to non-uniformity in mechanical properties, like internal stress and winding hardness differences in the transverse direction. Moreover, there can be a change in the mechanical properties of PET films at higher temperatures. In particular the Elastic Modulus of a PET film can sharply decreases e.g. above 110° C., and the resulting decrease in film stiffness negatively affects the film handling. The combination of these factors can have a strong impact on the winding performance (e.g. waves, wrinkle formation) at higher process heat loads, like heat loads inherent in Chemical Vapour Deposition (CVD) of, for instance, high quality SiNx barrier films (the coating drum temperature can be about 120° C.).

The embodiments of the present disclosure can further stabilize flexible substrates, such as PET films. In particular, the present disclosure provides a heat stabilization through heated winding under vacuum, allowing flexible substrates such as PET foils to relax in the transverse direction. A shrinkage subsequent of the stabilization process can be larger than that before the stabilization process and can counteract the thermal expansion during a CVD process. The stabilization process reduces the mechanical non-uniformities of the film, thus removing winding hardness non-uniformities in the transverse direction and consequently preventing waves and wrinkle formation.

An exemplary flexible substrate having a thickness of 125 m and a width of 1270 mm (i.e., a 1270 mm-wide roll) was heat treated using a first process phase (unwinding) with a drum temperature of 150° C., a web speed of 0.2 m/min, and unwinder/rewinder tensions of 750/730 N. A second process phase (rewinding) was performed with a drum temperature of 70° C., a web speed of 1.0 m/min, and unwinder/rewinder tensions of 750/730 N.

A web width of the exemplary flexible substrate measured before and after a process sequence (wind/rewind and CVD deposition) with a coating drum temperature of 120° C. had an initial web width of about 1270 mm and a final web width of 1266 mm. A constant web shrinkage after a CVD process (approximately 0.3%) was found (illustrated in FIG. 4B). Wrinkle-free CVD-coated (SiNx) barrier films using the vacuum-heat-stabilized PET substrates could be formed.

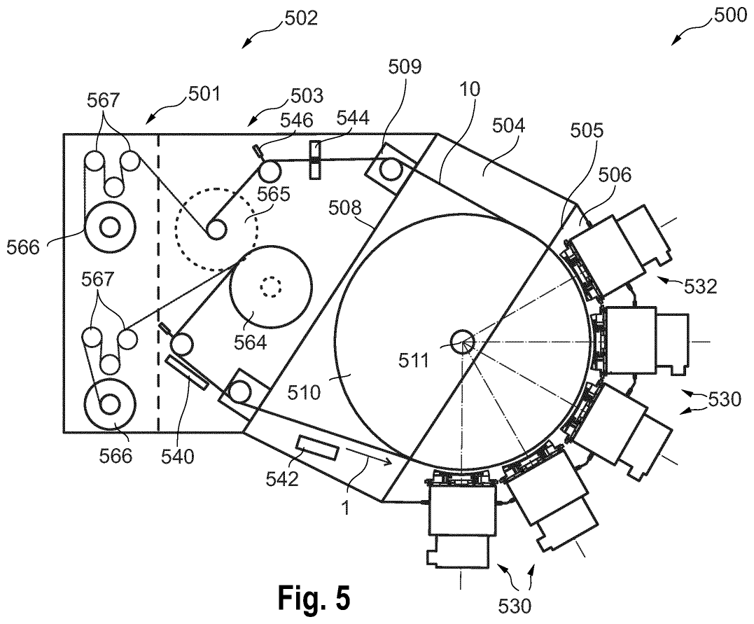

FIG. 5 shows a schematic view of a deposition apparatus 500 for depositing material on a flexible substrate 10, such as a roll-to-roll deposition apparatus according to embodiments described herein.

The deposition apparatus 500 includes a vacuum chamber, the heat treatment apparatus according to the present disclosure in the vacuum chamber, and one or more deposition devices 530 for depositing material on at least a surface of the flexible substrate 10. The heat treatment apparatus and the one or more deposition devices 530 can be provided in the same vacuum chamber or in separate vacuum chambers. In an exemplary embodiment, the drum and the one or more deposition devices 530 can be provided in the same vacuum chamber, such as a vacuum deposition chamber, or in separate vacuum chambers, such as a vacuum treatment chamber and a vacuum deposition chamber, respectively. In some implementations, the vacuum chamber in which the heat treatment apparatus is located is not configured for deposition. The flexible substrate 10 could be wound off a reel, heat treated under tension on the drum, and wound again, ready to be loaded into a vacuum deposition chamber of the deposition apparatus 500.

According to some embodiments, which can be combined with other embodiments described herein, deposition apparatus 500 includes a coating drum 510 rotatable around a rotational axis 511. In some examples, the drum can be provided as another drum. The heating device, and particularly the drum, can be positioned before the one or more deposition devices and/or the coating drum 510 e.g. with respect to a transport direction of the flexible substrate 10 (e.g., a substrate movement direction 1). In other examples, the coating drum 510 can be the drum. In particular, the coating drum 510 could act as the drum with the one or more deposition devices 530 being switched off to perform the heat treatment.

The one or more deposition devices 530 and optionally one or more further processing devices 532, such as one or more etching tools, can be positioned adjacent to the coating drum 510. The deposition apparatus 500 can include at least three chamber portions, such as a first chamber portion 502, a second chamber portion 504 and a third chamber portion 506. The third chamber portion 506 or a combination of the second chamber portion 504 and the third chamber portion 506 can be configured as the vacuum chamber, such as the vacuum deposition chamber and/or the vacuum treatment chamber, of the present disclosure. The one or more deposition devices 530 and the one or more further processing devices 532 can be provided in the third chamber portion 506.

The flexible substrate 10 is provided on a first roll 564, e.g. having a winding shaft. The flexible substrate 10 is unwound from the first roll 564 as indicated by the substrate movement direction 1. A separation wall 508 is provided for separation of the first chamber portion 502 and the second chamber portion 504. The separation wall 508 can further be provided with gap sluices 509 for having the flexible substrate 10 pass therethrough. A vacuum flange 505 between the second chamber portion 504 and the third chamber portion 506 may be provided with openings to take up the one or more processing tools, such as the one or more deposition devices 530 and the one or more further processing devices 532.

The flexible substrate 10 is moved through the deposition areas (or coating areas) provided at the coating drum 510 and corresponding to positions of the one or more deposition devices 530. During operation, the coating drum 510 rotates around the rotational axis 511 such that the flexible substrate 10 moves in the substrate movement direction 1. According to some embodiments, the flexible substrate 10 is guided via one, two or more rollers from the first roll 564 to the coating drum 510 and from the coating drum 510 to a second roll 565, e.g. having a winding shaft, on which the flexible substrate is wound after processing thereof.

In some implementations, the first chamber portion 502 is separated in an interleaf chamber portion unit 501 and a substrate chamber portion unit 503. Interleaf rolls 566 and interleaf rollers 567 can be provided as a modular element of the deposition apparatus 500. The deposition apparatus 500 can further include a pre-heating unit 540 to heat the flexible substrate 10. Further, additionally or alternatively a pre-treatment plasma source 542, e.g., an RF plasma source can be provided to treat the flexible substrate 10 with a plasma prior to entering the third chamber portion 506.

According to yet further embodiments, which can be combined with other embodiments described herein, optionally an optical measurement unit 544 for evaluating the result of the substrate processing and/or one or more ionization units 546 for adapting the charge on the flexible substrate 10 can be provided.

In some implementations, the coating drum 510 includes a cooling device configured to cool the support surface of the coating drum 510, for example, during substrate processing. The cooling of the support surface can reduce heat damage of the flexible substrate 10, for example, during a coating process. According to some embodiments, the coating drum 510 can be a double-walled coating drum. A cooling liquid can be provided between the two walls of the double-ward coating drum. The two walls can be an inner wall and an outer wall, wherein the outer wall can provide the support surface.

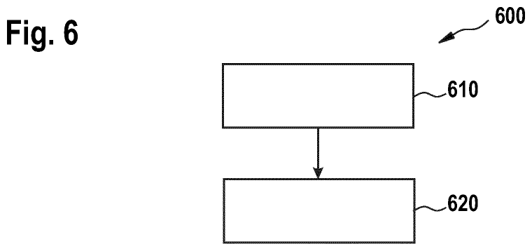

FIG. 6 shows a flow chart of a method 600 for processing a flexible substrate according to embodiments described herein.

The method 600 for processing a flexible substrate includes the method 300 of heat treatment of a flexible substrate in a vacuum chamber, and in particular the transporting of the flexible substrate, the applying of a tension to the flexible substrate in a longitudinal direction, and the heating, by a drum, of the flexible substrate to a first temperature of 120° C. to 180° C. (block 610). The method 600 for processing a flexible substrate further includes depositing material on at least a surface of the flexible substrate (block 620). The material can be deposited using for instance a CVD process. In some embodiments, a barrier film, such as a SiNx film, can be deposited on the vacuum-heat stabilized flexible substrate.

According to some embodiments, the method 600 further includes a rotating of a coating drum around a rotational axis to move the flexible substrate through a processing area provided in the vacuum deposition chamber. In some implementations, the method 600 includes a processing of the flexible substrate in the processing area. The processing of the flexible substrate can include at least one of depositing a material layer on the flexible substrate and performing an etching process.

According to embodiments described herein, the method for processing a flexible substrate can be conducted using of computer programs, software, computer software products and the interrelated controllers, which can have a CPU, a memory, a user interface, and input and output devices being in communication with the corresponding components of the apparatuses according to the present disclosure.

The present disclosure provides a heat stabilization through heated winding under vacuum, allowing a flexible substrate, such as a PET film or foil, to relax particularly in the transverse direction. The stabilization process reduces mechanical non-uniformities. Winding hardness non-uniformities in the transverse direction can be removed and the formation of waves and wrinkles can be reduced or even avoided.

While the foregoing is directed to embodiments of the disclosure, other and further embodiments of the disclosure may be devised without departing from the basic scope thereof, and the scope thereof is determined by the claims that follow.

1. A heat treatment apparatus for use in a vacuum chamber, comprising:
a transport arrangement configured to apply a tension to a flexible substrate in a longitudinal direction, wherein the transport arrangement comprises a drum; and
a heating device configured to heat the drum for heating the flexible substrate to a first temperature of 120° C. to 180° C.

2. The heat treatment apparatus of claim 1, wherein the drum is rotatable in a first direction and a second direction opposite the first direction and configured to heat the flexible substrate to the first temperature during the rotation in the first direction.

3. The heat treatment apparatus of claim 2, wherein the drum is configured to heat the flexible substrate to a second temperature of 40° C. to 100° C. during the rotation in the second direction.

4. The heat treatment apparatus of claim 1, wherein the transport arrangement includes a first roller and a second roller, and wherein the first roller, the drum and the second roller are sequentially arranged along a transport path of the flexible substrate.

5. The heat treatment apparatus of claim 4, wherein the first roller is an unwinding roller and the second roller is a winding roller when the drum rotates in the first direction, and wherein the first roller is a winding roller and the second roller is an unwinding roller when the drum rotates in the second direction.

6. The heat treatment apparatus of claim 1, wherein the transport arrangement is configured to apply a tension of 200 to 900N to the flexible substrate.

7. The heat treatment apparatus of claim 1, wherein the transport arrangement is configured to transport the flexible substrate with a speed of 0.1 to 5 m/min.

8. A deposition apparatus for depositing material on a flexible substrate, comprising:
a vacuum chamber;
a heat treatment apparatus of for use in a vacuum chamber wherein the heat treatment apparatus comprises:
a transport arrangement configured to apply a tension to a flexible substrate in a longitudinal direction, wherein the transport arrangement comprises a drum; and
a heating device configured to heat the drum for heating the flexible substrate to a first temperature of 120° C. to 180° C.; and wherein the deposition apparatus further comprises
one or more deposition devices for depositing material on at least a surface of the flexible substrate, wherein the heating device is positioned before the one or more deposition devices.

9. A method of heat treatment of a flexible substrate in a vacuum chamber, comprising:
transporting the flexible substrate;
applying a tension to the flexible substrate in a longitudinal direction; and
heating, using a drum, the flexible substrate to a first temperature of 120° C. to 180° C.

10. A method for processing a flexible substrate, comprising:
transporting the flexible substrate;
applying a tension to the flexible substrate in a longitudinal direction;
heating, using a drum, the flexible substrate to a first temperature of 120° C. to 180° C.; and
depositing material on at least a surface of the flexible substrate.

11. The method of claim 9, wherein transporting the flexible substrate comprises:
transporting the flexible substrate by rotating the drum in a first direction and subsequently in a second direction opposite to the first direction.

12. The method of claim 11, wherein the flexible substrate is heated to the first temperature during the rotation in the first direction and to a second temperature lower than the first temperature during the rotation in the second direction.

13. The method of claim 10, wherein the flexible substrate is transported with a speed of 0.1 to 5 m/min.

14. The method of claim 10, wherein the flexible substrate is transported with a first speed during the rotation of the drum in the first direction and with a second speed lower than the first speed during the rotation of the drum in the second direction.

15. The method of claim 10, wherein a tension of 200N to 900N is applied to the flexible substrate in the longitudinal direction.

16. The heat treatment apparatus of claim 3, wherein the transport arrangement is configured to apply a tension of 200 to 900N to the flexible substrate

17. The deposition apparatus of claim 8, wherein the transport arrangement is configured to apply a tension of 200 to 900N to the flexible substrate.

18. The method of claim 10, wherein transporting the flexible substrate comprises:
transporting the flexible substrate by rotating the drum in a first direction and subsequently in a second direction opposite to the first direction.

19. The method of claim 18, wherein the flexible substrate is heated to the first temperature during the rotation in the first direction and to a second temperature lower than the first temperature during the rotation in the second direction.

20. The method of claim 11, wherein a tension of 200N to 900N is applied to the flexible substrate in the longitudinal direction.
